(19) United States
(12) Patent Application Publication
(10) Pub. No.: US 2018/0269853 A1
(43) Pub. Date: Sep. 20, 2018

(54) SURFACE ACOUSTIC WAVE WAFER LEVEL PACKAGE AND METHOD OF MANUFACTURING PCB FOR THE SAME

(71) Applicant: WISOL CO., LTD., Gyeonggi-do (KR)

(72) Inventors: Hun Yong LEE, Gyeonggi-do (KR); Jung Hoon HAN, Gyeonggi-do (KR)

(73) Assignee: WISOL CO., LTD.

(21) Appl. No.: 15/458,538

(22) Filed: Mar. 14, 2017

(51) Int. Cl. H03H 9/64; H03H 3/08; H03H 9/145; H03H 9/05; H03H 9/25

(52) U.S. Cl. CPC H03H 9/64; H03H 3/08; H03H 2009/0019; H03H 9/058; H03H 9/25; H03H 9/14541

(57) ABSTRACT

Disclosed is a surface acoustic wave wafer level package including a substrate, an interdigital transducer (IDT) electrode formed on the substrate, a connecting electrode formed on the substrate and electrically connected to the IDT electrode, a printed circuit board (PCB) with a through hole formed at a position corresponding to the connecting electrode, a hollow to accommodate the IDT electrode, and a bottom partially adhered to the substrate, and a connecting terminal electrically connected to the connecting electrode through the through hole.

### FIELD

The present disclosure relates to a surface acoustic wave device, and more particularly, to a surface acoustic wave wafer level package and a method of manufacturing a printed circuit board (PCB) for forming a hollow to accommodate an interdigital transducer (IDT) electrode in the surface acoustic wave wafer level package.

### BACKGROUND

A surface acoustic wave is an acoustic wave propagated along a surface of an elastic substrate. An acoustic wave is generated from an electrical signal as a result of a piezoelectric effect. An electric field of the acoustic wave may be concentrated on near the surface of the substrate and may interact with a conducting electron of another semiconductor disposed directly on the surface. A medium through which an acoustic wave is propagated is a piezoelectric material with a high electro-mechanical coupling efficient and a low acoustic wave energy loss, and a semiconductor may provide an optimal efficiency due to high mobility of a conducting electron, an optimal specific resistance, and a low direct current (DC) power element. A surface acoustic wave (SAW) device is obtained by replacing an electronic circuit with an electro-mechanical device using interaction between the surface acoustic wave and a semiconductor conducting electron.

Since wave energy of a surface acoustic wave is propagated while concentrated on a solid surface, it is easy to control a signal and it is possible to miniaturize a device. Also, due to the advent of a piezoelectric material of high quality such as LiNbO3, LiTaO3, quartz, PZT, an interdigital transducer (IDT) is installed on the surface to easily and efficiently generate, detect, and control a surface acoustic wave. As a result, various high functional electronic devices that process radio frequency signals with surface acoustic waves have studied and developed with increasing speed.

A surface acoustic wave device is configured to install interdigital shaped input electrode and output electrode at both ends with a thin metal film on a surface of a medium, input high frequency, convert into a surface acoustic wave, and detect radio wave properties to the output electrode to return to an electric signal. As an example of applying the same, there are a delay line device, an amplifier, a mode transformer, an optical beam deflector, an optical switch and the like.

In manufacturing such surface acoustic wave devices and semiconductor devices, recently, unlike an existing method of wafer processing, cutting chips one by one, and packaging, a manufacturing method using a wafer level package (WLP) in which a package process and a test is performed at a wafer level at one time and chips are cut to simply manufacture complete products has been generally used.

Through the WLP, packages as complete products may be manufactured at a wafer level, that is, in a state in which individual chips are not separated from a wafer. Also, existing wafer manufacturing facilities and processes may be used as they are for manufacturing facilities and manufacturing processes used for manufacturing packages. Since such WLP process performs a packaging process at a wafer level, compared with an existing method of packaging by an individual chip, several hundreds or several thousands of packages may be manufactured through one packing process, thereby sharply reducing manufacturing costs and investment costs.

In a surface acoustic wave wafer level package, since an IDT electrode is disposed in a hollow formed by a substrate, sidewalls, and a cover and mechanical vibrations of the IDT electrode is used for operating as a filter, it is necessary to completely protect the hollow. However, there is a limitation in adequately enduring high pressure in a process of manufacturing electronic devices including surface acoustic wave devices manufactured using a WLP method, particularly, in a transfer molding operation.

To overcome the same, there is a case of forming sidewalls and a cover using a hard material like a substrate. However, manufacturing costs are very high and a yield is low.

To overcome the limitation, U.S. Pat. No. 8,436,514 (patent document 1) discloses adding a conductive layer to a top of a protective cover to endure pressure caused by a transfer molding. Particularly, in patent document 1, it is disclosed that the conductive layer is broadly formed above a piezoelectric device to efficiently endure pressure and an area of the conductive layer is formed to be 50% or more of an area of a top surface of the piezoelectric device.

However, the method of patent document 1 causes other limitations. When a conductive layer is broadly formed above a protect cover, a warpage phenomenon in which a substrate of a piezoelectric device is warped occurs. When a substrate is formed to be thick to prevent the same, it goes against the stream of thinning piezoelectric devices. Also, when a WLP process is performed on a thick substrate and the substrate is ground, manufacturing costs are increased and a yield becomes lowered due to adding of process.

A single crystal material such as LiTa2O3 is generally used as substrates. However, such material is easily broken by an external physical shock. Accordingly, it is necessary to handle with care in process. As the warpage of a substrate gets greater, many limitations in process are caused.

For example, when a laminating process or a coating process for forming an insulation layer is applied after forming a conductive layer, it is necessary to dispose a substrate on a vacuum chuck and to level the substrate using a vacuum. However, a warped substrate described above is easily broken in this process or an insulation layer forming material is not uniformly applied. In addition, a substrate is easily broken in a process of sawing a plurality of piezoelectric devices manufactured at a wafer level into one by one in a WLP manufacturing process.

Meanwhile, Korean Patent Registration No. 0836652 discloses a wafer level package having a structure in which vias are formed in a cap wafer formed of the same material as a piezoelectric wafer and the cap wafer is bonded to the piezoelectric wafer.

However, since piezoelectric materials are very high priced, an increase in price is caused. Also, it is not easy to process piezoelectric materials having hardness, and a possibility of being damaged or defective is high when vias are formed. Also, since there is a technical difficulty in bonding piezoelectric materials to each other, a yield is low.

[Patent Document]

Patent Document 1: US Patent Registration No. 8436514

Patent Document 2: Korean Patent Registration No. 0836652

### SUMMARY

It is an aspect of the present invention to provide a surface acoustic wave wafer level package capable of being easily via-processed, being miniaturized, and being thinned while using a low-priced material and including improved pressure-resistant properties.

It is another aspect of the present invention to provide a method of manufacturing a printed circuit board (PCB) for forming a hollow to accommodate an interdigital transducer (IDT) electrode for the surface acoustic wave wafer level package.

One aspect of the present invention provides a surface acoustic wave wafer level package including a substrate, an IDT electrode formed on the substrate, a connecting electrode formed on the substrate and electrically connected to the IDT electrode, a PCB with a through hole formed at a position corresponding to the connecting electrode, a hollow to accommodate the IDT electrode, and a bottom partially adhered to the substrate, and a connecting terminal electrically connected to the connecting electrode through the through hole.

The PCB may include a hollow former adhered to the substrate while having a step from a part opposite to the IDT electrode around the through hole to form the hollow.

The hollow former may include a thin copper film formed around the through hole and a plating layer formed on the thin copper film.

The PCB may further include a reinforcing layer at least partially disposed to be opposite to the IDT electrode to function as a reinforcing member.

The reinforcing layer may include a thin copper film formed below the PCB.

The reinforcing layer may include a thin copper film formed below the PCB and a thin copper film formed in the PCB.

The reinforcing layer may include a thin copper film formed in the PCB.

Another aspect of the present invention provides a method of manufacturing a PCB for forming a hollow to accommodate an IDT electrode in a surface acoustic wave wafer level package. The method includes (a) preparing a PCB raw material with thin copper films applied to both sides thereof, (b) forming a through hole at a position corresponding to a connecting electrode of the surface acoustic wave wafer level package, (c) maintaining the thin copper film at a first part including a periphery of the through hole at a top surface and a bottom surface and a second part at least partially opposite to the IDT electrode and removing other parts of the thin copper film, and (d) forming a plating layer on the thin copper film at the first part and an inner circumferential surface of the through hole.

The operation (c) may include applying a photoresist to the first part and the second part, removing other parts of the thin copper film except parts corresponding to the first part and the second part through an etching process, and removing the photoresist.

The operation (d) may include applying a plating resist to the thin copper film at the second part, forming a plating layer on the thin copper film of the first part and the inner circumferential surface of the through hole through a plating process, and removing the plating resist.

Still another aspect of the present invention provides a method of manufacturing a PCB for forming a hollow to accommodate an IDT electrode in a surface acoustic wave wafer level package. The method includes (a) manufacturing a PCB with thin copper films applied to both sides thereof and a thin copper film inserted in a part thereinside, (b) forming a through hole at a position corresponding to a connecting electrode of the surface acoustic wave wafer level package, (c) maintaining the thin copper film at a first part including a periphery of the through hole at a top surface and a bottom surface and a second part at least partially opposite to the IDT electrode and removing other parts of the thin copper film, and (d) forming a plating layer on the thin copper film at the first part and an inner circumferential surface of the through hole.

The operation (a) may include (a1) preparing a first PCB raw material with a thin copper film applied to one side thereof and a second PCB raw material with a thin copper film applied to both sides thereof, (a2) maintaining the thin copper film at the part is maintained and other parts of the thin copper film are removed from the one side of the second PCB raw material, and (a3) stacking and pressurizing the first PCB raw material and the second PCB raw material to allow another surface to which the thin copper film of the first PCB raw material is not applied to come into contact with a surface of the second PCB raw material from which the thin copper film is removed.

Yet another aspect of the present invention provides a method of manufacturing a PCB for forming a hollow to accommodate an IDT electrode in a surface acoustic wave wafer level package. The method includes (a) manufacturing a PCB with thin copper films applied to both sides thereof and a thin copper film inserted in a part thereinside, (b) forming a through hole at a position corresponding to a connecting electrode of the surface acoustic wave wafer level package, (c) maintaining the thin copper film at a first part including a periphery of the through hole at a top surface and a bottom surface and removing other parts of the thin copper film, and (d) forming a plating layer on the thin copper film at the first part and an inner circumferential surface of the through hole.

The operation (c) may include applying a photoresist to the first part, removing other parts of the thin copper film except a part corresponding to the first part through an etching process, and removing the photoresist.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIGS. 1A and 1B are views illustrating a structure of a surface acoustic wave wafer level package according to a first embodiment of the present invention;

FIGS. 2A and 2B illustrate examples of a top view taken along A-A′ of FIG. 1A;

FIGS. 3A and 3B illustrate examples of a top view taken along B-B′ of FIG. 1A;

FIG. 4 illustrates a process of manufacturing a PCB 30 of FIG. 1A according to one embodiment of the present invention;

FIGS. 5A and 5B are views illustrating a structure of a surface acoustic wave wafer level package according to a second embodiment of the present invention;

FIG. 6 illustrates a process of manufacturing a PCB 30′ of FIG. 5A according to one embodiment of the present invention;

FIG. 7 illustrates a process of manufacturing a PCB 300′ of FIG. 6 according to one embodiment of the present invention;

FIGS. 8A and 8B are views illustrating a structure of a surface acoustic wave wafer level package according to a third embodiment of the present invention; and

FIG. 9 illustrates a process of manufacturing a PCB 30″ of FIG. 8 according to one embodiment of the present invention.

### DETAILED DESCRIPTION

Hereinafter, exemplary embodiments of the present invention will be described in detail with reference to the drawings. Throughout the following description and attached drawings, substantially like components will be referred to as like reference numerals and a repeated description thereof will be omitted. Also, throughout the description of the embodiments of the present invention, a detailed explanation of well-known functions and components of the related art will be omitted when it is deemed that they may unnecessarily obscure the essence of the present invention.

Surface acoustic wave wafer level packages according to the embodiments of the present invention provide a structure capable of functioning as a sidewall and a cover while forming a hollow to accommodate an interdigital transducer (IDT) electrode using a printed circuit board (PCB). The PCB is low-priced material that reduces manufacturing costs, easy for various types of processing such as via processing, advantageous to be miniaturized and thinned, able to provide a hard structure to increase pressure-resistant properties.

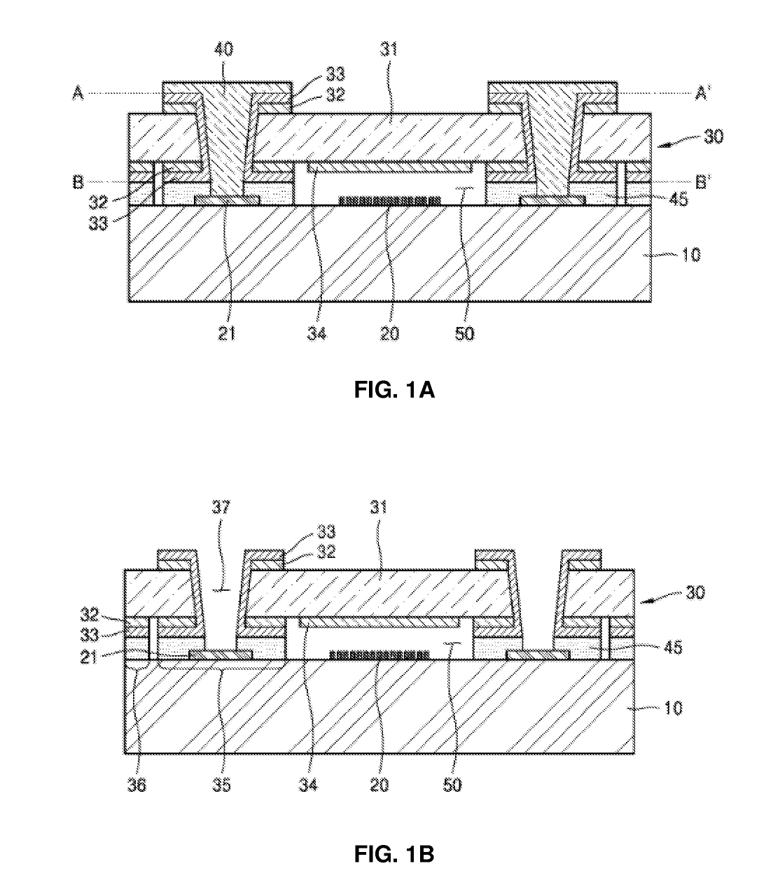

FIGS. 1A and 1B illustrate a structure of a surface acoustic wave wafer level package according to a first embodiment of the present invention. FIG. 1A illustrates a structure in which a substrate 10 and a PCB 30 are adhered and a connecting terminal 40 is formed, and FIG. 1B illustrates a structure the substrate 10 and the PCB 30 are adhered and the connecting terminal 40 is not formed yet.

Referring to FIG. 1, the surface acoustic wave wafer level package according to the first embodiment of the present invention includes a substrate 10, an IDT electrode 20 formed on the substrate 10, a connecting electrode 21 formed on the substrate 10 and electrically connected to the IDT electrode 20, a PCB 30 including a through hole 37 formed at a position corresponding to the connecting electrode 21, a hollow 50 formed to accommodate the IDT electrode 20, and a part of a bottom surface adhered to the substrate 10, and a connecting terminal 40 electrically connected to the connecting electrode 21 through the through hole 37.

The substrate 10 causes a piezoelectric effect and supports components of a device, and a piezoelectric substrate may be used. For example, a piezoelectric substrate formed of LiTa2O3, LiNbO3 or the like. The substrate 10 may be formed to be thin to miniaturize and thin the device. For example, in the embodiments of the present invention, the substrate 10 may have a thickness of about 250 μm or less.

The IDT electrode 20 is a component basically included in a surface acoustic wave device and is formed on the substrate 10. Through mechanical vibrations of the IDT electrode 20, the surface acoustic wave device operates as a filter and the like.

The connecting electrode 21 functions as a medium capable of electrically connecting the IDT electrode 20 to the outside of the surface acoustic wave device. For example, the connecting terminal 40 and the IDT electrode 20 are electrically connected through the connecting electrode 21, a signal input from an external terminal is transferred to the IDT electrode 20 through the connecting terminal 40 and the connecting electrode 21, and a signal generated by the IDT electrode 20 is transferred to the external terminal through the connecting electrode 21 and the connecting terminal 40. Meanwhile, the connecting electrode 21 and the connecting terminal 40 may be integrated, and depending on a shape and arrangement of the IDT electrode 20, the connecting electrode 21 may be omitted and the IDT electrode 20 may be directly connected to the connecting terminal 40. In this case, a contact part between the IDT electrode 20 and the connecting terminal 40 may be considered as the connecting electrode 21. As described above, according to a structure in which the connecting electrode 21 and the connecting terminal 40 are integrated, since the connecting electrode 21 and the connecting terminal 40 may be formed by a single process, operations of the process may be reduced and manufacturing costs may be reduced compared with a structure in which the connecting electrode 21 and the connecting terminal 40 are separately formed.

The PCB 30 accommodates the IDT electrode 20 using the hollow 50 and simultaneously functions as a cover substrate for electrically connecting the connecting electrode 21 to the connecting terminal 40.

The PCB 30 includes the through hole 37 at the position corresponding to the connecting electrode 21, and the connecting terminal 40 is electrically connected to the connecting electrode 21 through the through hole 37. The connecting terminal, as shown in the drawings, may be formed in a shape of filling the through hole 37 and may be formed in a shape of being electrically connected along an inner circumferential surface of the through hole 37 without filling the through hole 37. The connecting terminal 40 may be formed of Ti, Cu, Sn, Ni, Au or an alloy thereof and may be formed using a plating process.

To form the hollow 50 that accommodates the IDT electrode 20, the PCB 30 includes hollow formers 35 and 36 adhered to the substrate 10 with a height difference with a part opposite to the IDT electrode 20 (that is, a top of the IDT electrode 20) around the through hole 37 in a bottom surface of the PCB 30.

In detail, the hollow formers 35 and 36 include a thin copper film 32 formed on an outer circumferential surface of the through hole 37 and outside the through hole 37 and a plating layer 33 formed on the thin copper film 32 and form the hollow 50 by adhering the plating layer 33 to the substrate 10 through an adhesive 45. That is, a thickness of adding the plating layer 33 to the thin copper film 32 is formed to be thicker than a thickness of a reinforcing layer 34 that will be described below based on a PCB substrate 31 below the PCB 30 and the plating layer 33 and the substrate 10 are adhered using the adhesive 45 to from the hollow 50 capable of accommodating the IDT electrode 20.

In addition, the PCB 30 may further include, for example, the reinforcing layer 34 that functions as a reinforcing member to further endure pressure according to transfer molding. The reinforcing layer 34, as shown in the drawing, is disposed to allow at least a part to be opposite to the IDT electrode 20. According to the embodiment, as shown in the drawings, the reinforcing layer 34 may be formed of a thin copper film 34 formed on the bottom surface of the PCB 30. As an alternative embodiment, a reinforcing layer may be formed of a thin copper film formed inside the PCB 30 and may include both the thin copper film formed in the PCB 30 and a thin copper film formed on the bottom surface of the PCB 30. It will be described as an additional embodiment.

Like the embodiment, when the reinforcing layer 34 is formed of the thin copper film 34 formed on the bottom surface of the PCB 30, the thin copper film 32 that forms the hollow formers 35 and 36 and the thin copper film 34 that forms the reinforcing layer may be formed at the same time during a process of manufacturing the PCB 30 and may be performed through a patterning process of a traditional PCB manufacturing process. In addition, since a pattern for an inductor or a capacitor necessary for operations of a device may be formed at the same time while patterns of the thin copper films 32 and 34 are formed through one time of the patterning process, process efficiency may be increased.

Depending on embodiments, the thin copper film 34 that forms the reinforcing layer and the thin copper film 32 that forms the hollow former 36 may be formed to be separate from each other or may be formed to be connected to each other. For example, in a case in which properties are improved when grounded parts are connected due to properties of a required device, thin copper films surrounding through holes at the grounded part and the thin copper film 34 that forms the reinforcing layer may be formed to be mutually connected.

The plating layer 33 formed on the thin copper film 32 that forms the hollow formers 35 and 36 may also be formed through a plating operation of a general PCB manufacturing process. Here, to form a step, the thin copper film 34 that forms the reinforcing layer may be formed of a plating resist not to be plated. However, as an alternative example, when a thin copper film for a reinforcing layer is formed in a PCB, it is unnecessary to use a plating resist.

Since the thin copper film that forms the reinforcing layer is formed above the hollow formers 35 and 36 formed of the thin copper film 34 and the plating layer 33 even though being formed at a part opposite to the IDT electrode 20 below the PCB 30 like the embodiment, the thin copper film 34 may not come into contact with the IDT electrode 20 and the hollow formers 35 and 36 may be adhered to the substrate 10 by the adhesive 45.

Also, heights of the reinforcing layer 34 and the hollow formers 35 and 36 may be determined according to required pressure. For example, when a pressure of a transfer molding is 700 psi, a thickness of the reinforcing layer 34 may be 3 μm or more and thicknesses of the hollow formers 35 and 36 may be 7 μm or more. Adjustment of the thickness of the reinforcing layer 34 and the thicknesses of the hollow formers 35 and 36 may be easily achieved by adjusting thicknesses of the thin copper film and the plating layer during a PCB manufacturing process. As a required pressure is high, the thickness of the reinforcing layer 34 may be formed to be great. The reinforcing layer 34 may be formed of a plurality of layers in various shapes at a top surface and a bottom surface of a PCB, a top surface and inside, inside and a bottom surface, and additionally, all a top surface, a bottom surface, and inside.

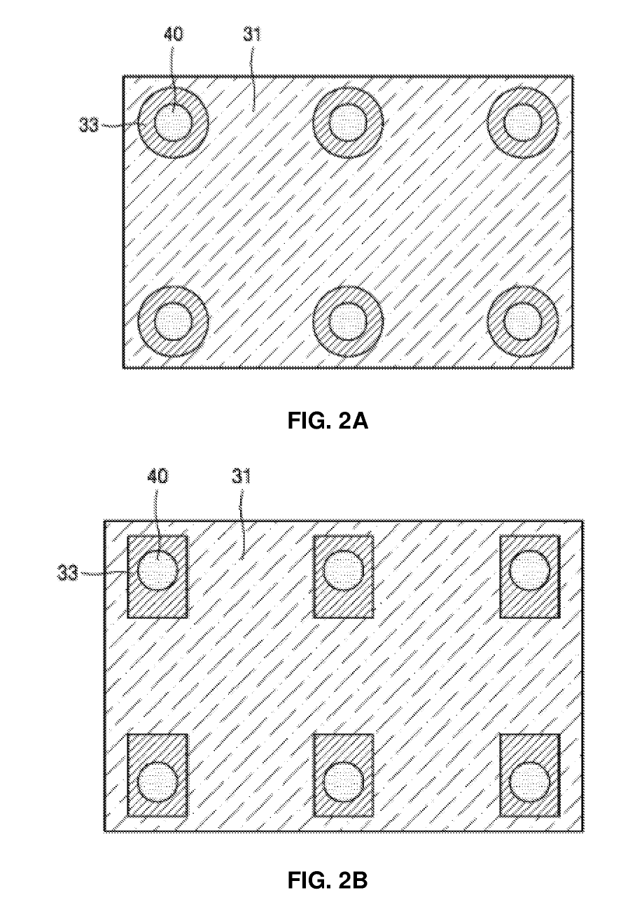

FIGS. 2A and 2B illustrate examples of a top view taken along A-A′ of FIG. 1A. Above the PCB 30, shapes of the thin copper film 32 and the plating layer 33 that surrounding the through hole 37 may be a circle as shown in FIG. 2A, may be a quadrangle as shown in FIG. 2B, and may be one of various other shapes. Above the PCB 30, a shape of the connecting terminal 40 may be identical to the shapes of the thin copper film 32 and the plating layer 33.

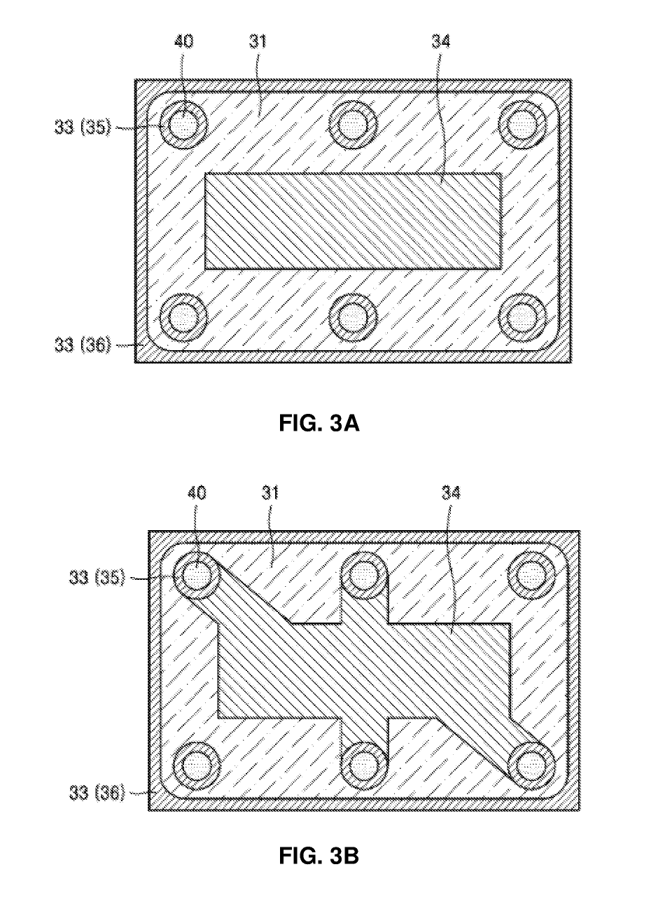

FIGS. 3A and 3B illustrate examples of a top view taken along B-B′ of FIG. 1A. Below the PCB 30, the hollow formers 35 and 36 may be divided into an inner hollow former 35 that surrounds the through hole 37 and an outer hollow former 36 outside the inner hollow former 35. The inner hollow former 35 and the outer hollow former 36 may be electrically separated. Since both the inner hollow former 35 and the outer hollow former 36 are formed of the thin copper film 32 and the plating layer 33, they may be formed at the same time in a process of manufacturing the PCB 30. The outer hollow former 36 is electrically separated from the inner hollow former 35 and formed at the outermost part of the device and is adhered to the substrate 10 with the inner hollow former 35.

The reinforcing layer 34, as shown in FIG. 3A, may be formed to be separated from the hollow formers 35 and 36. Unlike this, the reinforcing layer 34, as shown in FIG. 3B, may be formed to be electrically connected to some of the inner hollow formers 35. That is, in FIG. 3B, thin copper films that surround through holes at grounded parts are electrically connected through the reinforcing layer 34 to improve properties as described above.

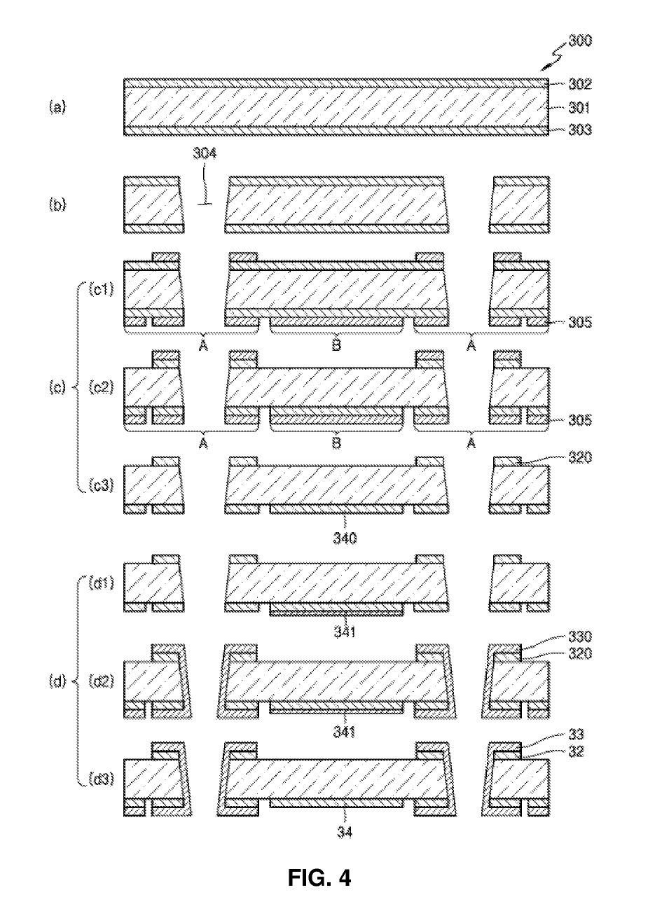

FIG. 4 illustrates a process of manufacturing the PCB 30 of FIG. 1A according to one embodiment of the present invention.

First, a PCB raw material 300 in which thin copper films 302 and 303 are applied to both sides of a PCB 301 (a).

Next, a through hole 304 is formed at a position corresponding to the connecting electrode 21 of a necessary surface acoustic wave wafer level package (b). The through hole 304 may be formed, for example, by processing using a laser drill, and a desmearing process may be performed after drilling.

Next, parts of the thin copper film at a first part A of the thin copper film including a periphery of the through hole 304 below and above the PCB raw material 300 in which the through hole 304 is formed and a second part B of the thin copper film partially opposite to the IDT electrode 20 below the PCB raw material 300 are maintained and other parts of the thin copper film are removed (c). In detail, a thin copper film 320 at the first part A and a thin copper film 340 of the second part B are formed by applying a photoresist 305 to the first part A and the second part B (c1), removing the other parts of the thin copper film except the first part A and the second part B through an etching process (c2), and then removing the photoresist 305 (c3).

Next, to form a step between the first part A and the second part B, a plating layer is formed on the thin copper film at the first part A and an inner circumferential surface of the through hole 304 (d). In detail, a plating resist 341 is applied to the thin copper film 340 at the second part B (d1), a plating layer 330 is formed on the thin copper film 320 at the first part A and the inner circumferential surface of the through hole 304 through a plating process (d2), and then the plating resist 341 is removed (d3).

Referring to (d3) of FIG. 4, the PCB 30 shown in FIG. 1 may be formed through the process including (a) to (d).

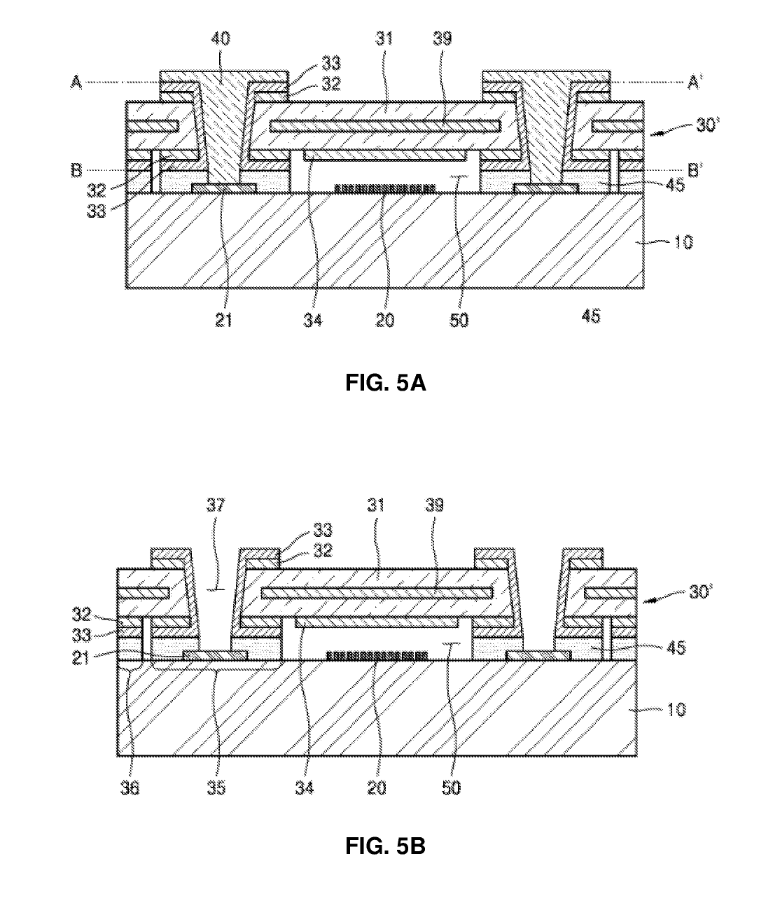

FIGS. 5A and 5B are views illustrating a structure of a surface acoustic wave wafer level package according to a second embodiment of the present invention. FIG. 5A illustrates a structure in which the substrate 10 and a PCB 30′ are adhered to each other and the connecting terminal 40 is formed, and FIG. 5B illustrates a structure in which the substrate 10 and the PCB 30′ are adhered to each other and the connecting terminal 40 is not yet formed.

As a difference between the second embodiment and the first embodiment, a reinforcing layer is formed of the thin copper film 34 formed below the PCB 30 in the first embodiment and a thin copper film 39 formed in the PCB 30′ is further provided in addition to the thin copper film 34 as reinforcing layers in the second embodiment. Since other structures and functions in addition to the difference described above are identical to the embodiment of FIG. 1, a repeated description will be omitted.

Since the thin copper film 39 formed in the PCB 30′ is added in the second embodiment, pressure-resistant properties are further increased than the first embodiment. The thin copper film 39 formed in the PCB 30′ is formed to be partially opposite to the IDT electrode 20 like the thin copper film 34 below the PCB 30′. Also, as shown in the drawings, the thin copper film 39 in the PCB 30′ may be formed to be broader than the thin copper film 34 below the PCB 30′.

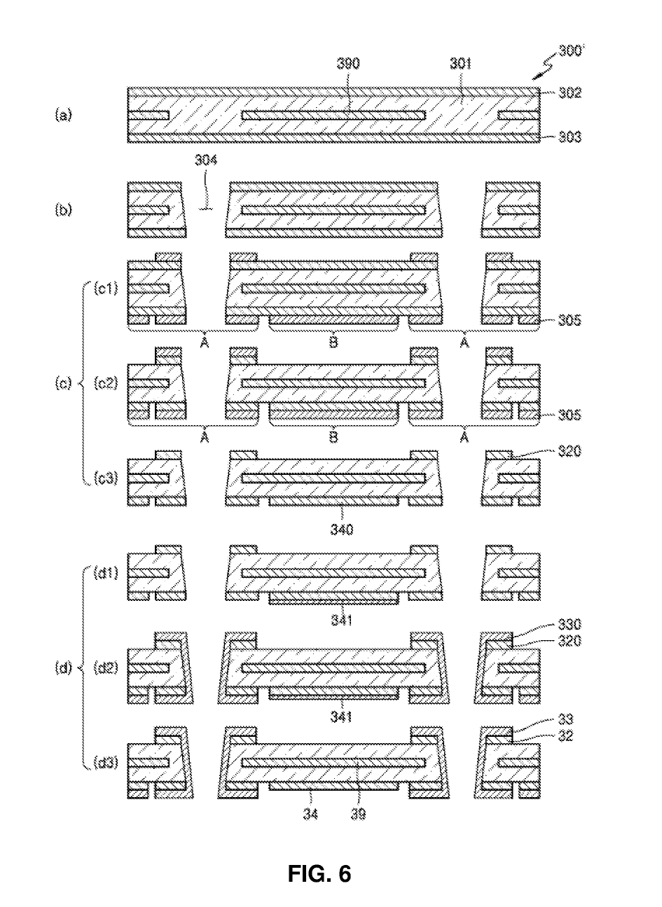

FIG. 6 illustrates a process of manufacturing the PCB 30′ of FIG. 5A according to one embodiment of the present invention. As a difference between the embodiment of FIG. 6 and the embodiment of FIG. 4, the PCB raw material 300 with the thin copper films 302 and 303 applied to the both sides of the PCB 301 is prepared in operation of a in FIG. 4 and the PCB 300′ not only with the thin copper films 302 and 303 applied to the both sides of the PCB 301 but also with a thin copper film 390 inserted in a part of the PCB 301 is prepared in operation (a) of FIG. 6. Since other structures and functions in addition to the difference described above are identical to the embodiment of FIG. 4, a repeated description will be omitted.

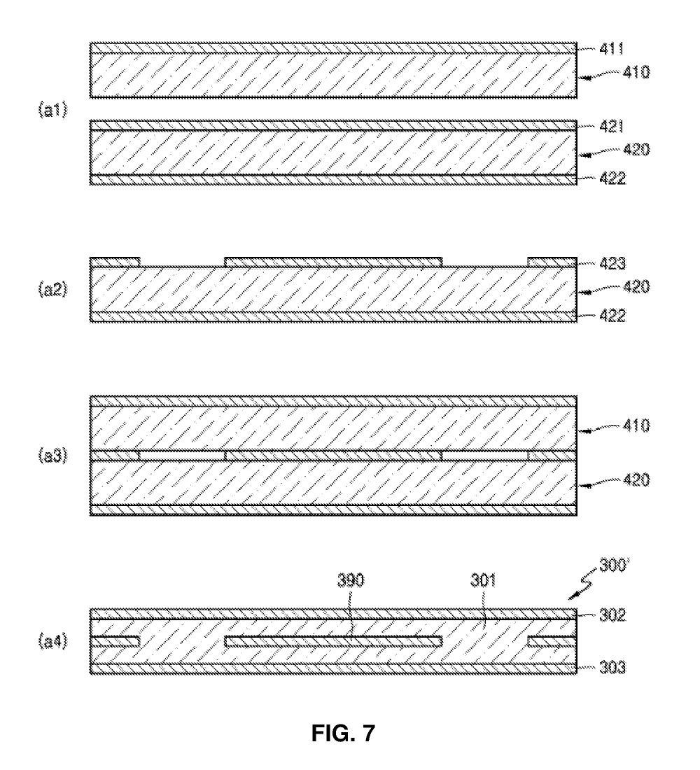

FIG. 7 illustrates a process of manufacturing the PCB 300′ of FIG. 6 according to one embodiment of the present invention.

First, a first PCB raw material 410 with a thin copper film 411 applied to one side and a second PCB raw material 420 with thin copper films 421 and 422 applied to both sides thereof are prepared (a1).

Next, a part 423 corresponding to the thin copper film 39 is maintained and other parts are removed from the thin copper film 421 on the one side of the second PCB raw material 420 (a2). This process may be performed through operations of applying a photoresist, etching, and removing the photoresist in a general PCB manufacturing process.

Next, another side of the first PCB raw material 410 to which the thin copper film 411 is not applied comes into contact with a surface of the second PCB raw material 420 from which the thin copper film is removed to stack and pressurize the first raw material 410 and the second PCB raw material 420 (a3).

Through the operation described above, the PCB 300′ as shown in FIG. 6(a) may be manufactured.

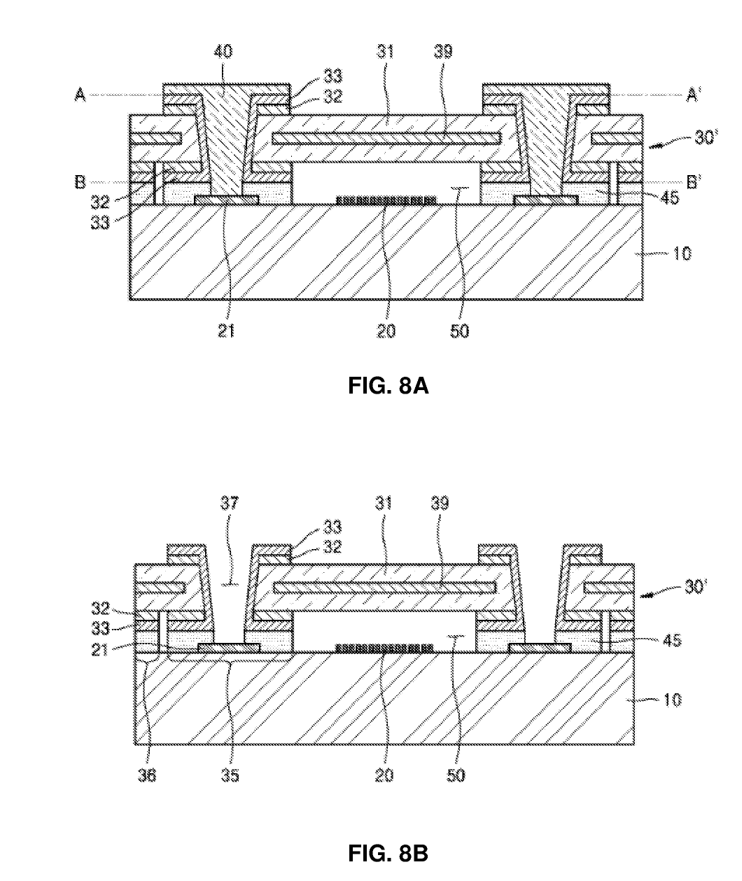

FIGS. 8A to 8B are views illustrating a structure of a surface acoustic wave wafer level package according to a third embodiment of the present invention. FIG. 8A illustrates a structure in which the substrate 10 and a PCB 30″ are adhered to each other and the connecting terminal 40 is formed, and FIG. 8B illustrates a structure in which the substrate 10 and the PCB 30″ are adhered to each other and the connecting terminal 40 is not yet formed.

As differences among the third embodiment and the first and second embodiments, only the thin copper film 34 formed below the PCB 30 is provided as a reinforcing layer in the first embodiment, both the thin copper film 34 formed below the PCB 30′ and the thin copper film 39 formed in the PCB 30′ are provided as reinforcing layers in the second embodiment, and only the thin copper film 39 formed in the PCB 30″ is provided as a reinforcing layer in the third embodiment. Since other structures and functions in addition to the differences described above are identical to the first and second embodiments, a repeated description will be omitted.

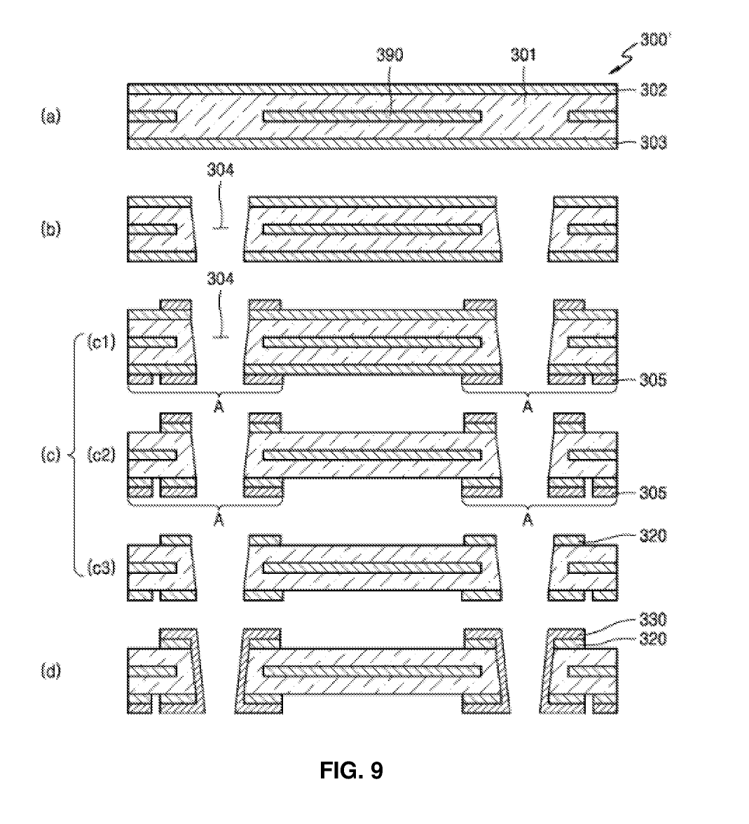

FIG. 9 illustrates a process of manufacturing the PCB 30″ of FIG. 8A according to one embodiment of the present invention.

First, like FIG. 6, the PCB 300′ not only with the thin copper films 302 and 303 applied to the both sides of the PCB 301 but also with the thin copper film 390 inserted in the part of the PCB 301 is manufactured and prepared (a).

Next, the through hole 304 is formed at a position corresponding to the connecting electrode 21 of a required surface acoustic wave wafer level package (b).

Next, the thin copper film at the first part A including a periphery of the through hole 304 is maintained and other parts of the thin copper film below and above the PCB 300′ in which the through hole 304 is formed are removed (c). In detail, the thin copper film 320 at the first part A is formed by applying the photoresist 305 to the first part A (c1), removing the other parts of the thin copper film except the first part A through an etching process (c2), and removing the photoresist 305 (c3).

Next, the plating layer 330 is formed on the thin copper film 320 at the first part A and an inner circumferential surface of the through hole 304 through a plating process (d).

According to the embodiments of the present invention, hardness is provided to allow a PCB and a thin copper film opposite to an IDT electrode of the PCB to resist high pressure and a double layer of a thin copper film and a plating layer formed around a through hole of the PCB forms a hollow.

Accordingly, a surface acoustic wave wafer level package according to the embodiments of the present invention may satisfy pressure-resistant properties, be simply processed, be reduced in manufacturing costs, and easily form a hollow, have less manufacturing processes to provide a high yield and increased reliability.

In addition, the thin copper film formed on the PCB may function as a reinforcing layer or form a hollow, may be used as an impedance circuit such as an inductor and the like, and may be utilized as a means for being electrically connected to a ground.

According to the embodiments of the present invention, there is provided a surface acoustic wave wafer level package capable of being easily via-processed, being miniaturized, and being thinned while using a low-priced material and including improved pressure-resistant properties.

Also, a PCB for forming a hollow to accommodate an IDT electrode in the surface acoustic wave wafer level package may be manufactured.

While the exemplary embodiments of the present invention have been described above, it should be understood by one of ordinary skill in the art that the present invention may be modified without departing from the essential features of the present invention. Therefore, the disclosed embodiments should be considered not in a limitative point of view but in a descriptive point of view. It should be appreciated that the scope of the present invention is defined by the claims not by the above description and includes all differences within the equivalent scope thereof.

What is claimed is:

1. A surface acoustic wave wafer level package comprising:
a substrate;
an interdigital transducer (IDT) electrode formed on the substrate;
a connecting electrode formed on the substrate and electrically connected to the IDT electrode;
a printed circuit board (PCB) with a through hole formed at a position corresponding to the connecting electrode, a hollow to accommodate the IDT electrode, and a bottom partially adhered to the substrate; and
a connecting terminal electrically connected to the connecting electrode through the through hole.

2. The surface acoustic wave wafer level package of claim 1, wherein the PCB comprises a hollow former adhered to the substrate while having a step from a part opposite to the IDT electrode around the through hole to form the hollow.

3. The surface acoustic wave wafer level package of claim 2, wherein the hollow former comprises a thin copper film formed around the through hole and a plating layer formed on the thin copper film.

4. The surface acoustic wave wafer level package of claim 2, wherein the PCB further comprises a reinforcing layer at least partially disposed to be opposite to the IDT electrode to function as a reinforcing member.

5. The surface acoustic wave wafer level package of claim 4, wherein the reinforcing layer comprises a thin copper film formed below the PCB.

6. The surface acoustic wave wafer level package of claim 4, wherein the reinforcing layer comprises a thin copper film formed below the PCB and a thin copper film formed in the PCB.

7. The surface acoustic wave wafer level package of claim 4, wherein the reinforcing layer comprises a thin copper film formed in the PCB.

8. A method of manufacturing a PCB for forming a hollow to accommodate an IDT electrode in a surface acoustic wave wafer level package, the method comprising:
(a) preparing a PCB raw material with thin copper films applied to both sides thereof;
(b) forming a through hole at a position corresponding to a connecting electrode of the surface acoustic wave wafer level package;
(c) maintaining the thin copper film at a first part comprising a periphery of the through hole at a top surface and a bottom surface and a second part at least partially opposite to the IDT electrode and removing other parts of the thin copper film; and
(d) forming a plating layer on the thin copper film at the first part and an inner circumferential surface of the through hole.

9. The method of claim 8, wherein operation (c) comprises:
applying a photoresist to the first part and the second part;
removing other parts of the thin copper film except parts corresponding to the first part and the second part through an etching process; and
removing the photoresist.

10. The method of claim 8, wherein operation (d) comprises:
applying a plating resist to the thin copper film at the second part;
forming a plating layer on the thin copper film of the first part and the inner circumferential surface of the through hole through a plating process; and
removing the plating resist.

11. A method of manufacturing a PCB for forming a hollow to accommodate an IDT electrode in a surface acoustic wave wafer level package, the method comprising:
(a) manufacturing a PCB with thin copper films applied to both sides thereof and a thin copper film inserted in a part thereinside;
(b) forming a through hole at a position corresponding to a connecting electrode of the surface acoustic wave wafer level package;
(c) maintaining the thin copper film at a first part comprising a periphery of the through hole at a top surface and a bottom surface and a second part at least partially opposite to the IDT electrode and removing other parts of the thin copper film; and
(d) forming a plating layer on the thin copper film at the first part and an inner circumferential surface of the through hole.

12. The method of claim 11, wherein operation (c) comprises:
applying a photoresist to the first part and the second part;
removing other parts of the thin copper film except parts corresponding to the first part and the second part through an etching process; and
removing the photoresist.

13. The method of claim 11, wherein operation (d) comprises:
applying a plating resist to the thin copper film at the second part;
forming a plating layer on the thin copper film of the first part and the inner circumferential surface of the through hole through a plating process; and
removing the plating resist.

14. The method of claim 11, wherein operation (a) comprises:
(a1) preparing a first PCB raw material with a thin copper film applied to one side thereof and a second PCB raw material with a thin copper film applied to both sides thereof;
(a2) maintaining the thin copper film at the part is maintained and other parts of the thin copper film are removed from the one side of the second PCB raw material; and
(a3) stacking and pressurizing the first PCB raw material and the second PCB raw material to allow another surface to which the thin copper film of the first PCB raw material is not applied to come into contact with a surface of the second PCB raw material from which the thin copper film is removed.

15. A method of manufacturing a PCB for forming a hollow to accommodate an IDT electrode in a surface acoustic wave wafer level package, the method comprising:
(a) manufacturing a PCB with thin copper films applied to both sides thereof and a thin copper film inserted in a part thereinside;
(b) forming a through hole at a position corresponding to a connecting electrode of the surface acoustic wave wafer level package;
(c) maintaining the thin copper film at a first part comprising a periphery of the through hole at a top surface and a bottom surface and removing other parts of the thin copper film; and
(d) forming a plating layer on the thin copper film at the first part and an inner circumferential surface of the through hole.

16. The method of claim 15, wherein operation (c) comprises:
applying a photoresist to the first part;
removing other parts of the thin copper film except a part corresponding to the first part through an etching process; and
removing the photoresist.

17. The method of claim 15, wherein operation (a) comprises:
(a1) preparing a first PCB raw material with a thin copper film applied to one side thereof and a second PCB raw material with a thin copper film applied to both sides thereof;
(a2) maintaining the thin copper film at the part is maintained and other parts of the thin copper film are removed from the one side of the second PCB raw material; and
(a3) stacking and pressurizing the first PCB raw material and the second PCB raw material to allow another surface to which the thin copper film of the first PCB raw material is not applied to come into contact with a surface of the second PCB raw material from which the thin copper film is removed.
